(19) United States
(12) Patent Application Publication
(10) Pub. No.: US 2024/0334734 A1
(43) Pub. Date: Oct. 3, 2024

(54) LIGHT-EMITTING DEVICES AND DISPLAY PANELS

(71) Applicant: WUHAN CHINA STAR OPTOELECTRONICS SEMICONDUCTOR DISPLAY TECHNOLOGY CO., LTD., Wuhan (CN)

(72) Inventors: Li YUAN, Wuhan (CN); Yu ZHANG, Wuhan (CN); Xiaosu JIANG, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 18/360,816

(22) Filed: Jul. 28, 2023

Related U.S. Application Data
(63) Continuation of application No. PCT/CN2023/093753, filed on May 12, 2023.

(30) Foreign Application Priority Data
Mar. 31, 2023 (CN) 202310350820.2

(51) Int. Cl. H10K 50/19; C09K 11/06

(52) U.S. Cl. CPC H10K 50/19; C09K 11/06; C09K 2211/1029; C09K 2211/1033; C09K 2211/1037; C09K 2211/1044; C09K 2211/185; H10K 50/12; H10K 85/342; H10K 85/346

(57) ABSTRACT

Disclosed are a light-emitting device and a display panel. A light-emitting functional layer includes a first light-emitting layer, a charge-generating layer, and a second light-emitting layer sequentially disposed on a first electrode. The first light-emitting layer includes a first light-emitting sublayer, and the second light-emitting layer includes a second light-emitting sublayer. A triplet lifetime of a material of the first light-emitting sublayer is longer than that of a material of the second light-emitting sublayer, and luminous efficiency of the material of the first light-emitting sublayer is less than that of the material of the second light-emitting sublayer.

### CROSS-REFERENCE TO RELATED APPLICATIONS

This application is a continuation of International Application No. PCT/CN2023/093753, filed on May 12, 2023, which claims priority to Chinese Patent Application No. 202310350820.2, filed on Mar. 31, 2023. The disclosures of the aforementioned applications are incorporated herein by reference in their entireties.

### TECHNICAL FIELD

The present disclosure relates to the field of display, and in particular, to a light-emitting device and a display panel.

### BACKGROUND

Organic light-emitting display panels (OLEDs) have been widely used in people's lives, such as display screens of mobile phones, computers, and vehicles. With the development of display technology and the requirement for the progress thereof, the demand for a display quality of the display panel, such as brightness and lifetime, is increasing. A tandem light-emitting device having a double-layer light-emitting unit has been developed to improve the brightness, the lifetime and other performance of the display panel.

However, the existing tandem light-emitting device still has problems that the luminous efficiency is not high enough, the brightness fails to meet a use requirement, and the lifetime of the light-emitting device is not long enough.

### SUMMARY

An embodiment of the present disclosure provides a light-emitting device and a display panel, which can solve the problems that the luminous efficiency of the existing tandem light-emitting device is not high enough, the brightness fails to meet the use requirement, and the lifetime of the light-emitting device is not long enough.

An embodiment of the present disclosure provides a light-emitting device including:
a substrate; a first electrode disposed on the substrate;
a light-emitting functional layer disposed on a side of the first electrode away from the substrate, the light-emitting functional layer including a first light-emitting layer, a charge-generating layer, and a second light-emitting layer sequentially disposed on the first electrode, the first light-emitting layer including a first light-emitting sublayer, and the second light-emitting layer including a second light-emitting sublayer; and
a second electrode disposed on a side of the second light-emitting layer away from the charge-generating layer;
wherein a triplet lifetime of a material of the first light-emitting sublayer is longer than that of a material of the second light-emitting sublayer, and luminous efficiency of the material of the first light-emitting sublayer is less than that of the material of the second light-emitting sublayer.

Optionally, in some embodiments of the present disclosure, wherein the first light-emitting sublayer includes a first host material and a first doping material, the first doping material including a first phosphorescent light-emitting material; and
the material of the second light-emitting sublayer includes a second host material and a second doping material, the second doping material including a second phosphorescent light-emitting material.

Optionally, in some embodiments of the present disclosure, wherein the first doping material includes an iridium (III) complex, the second doping material includes a platinum (II) complex, and ligands of each of the iridium (III) complex and the platinum (II) complex are organic multidentate ligands.

Optionally, in some embodiments of the present disclosure, wherein one or more of the ligands of the iridium (III) complex include at least an organic compound containing a dibenzofuran substituent.

Optionally, in some embodiments of the present disclosure, wherein one or more of the ligands of the iridium (III) complex include at least a deuterium group.

Optionally, in some embodiments of the present disclosure, wherein the iridium (III) complex includes any one of the following compounds:

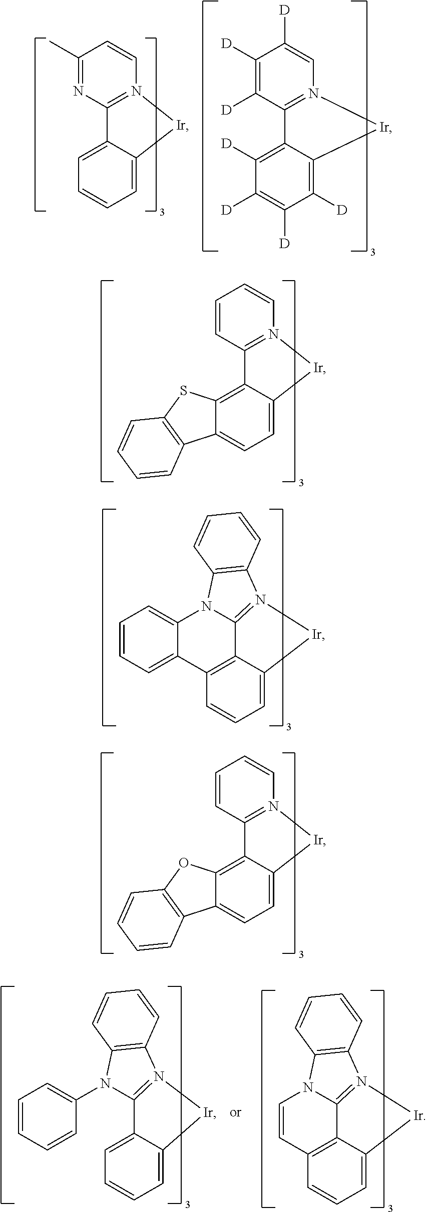

Optionally, in some embodiments of the present disclosure, wherein one or more of the ligands of the platinum (II) complex include an organic compound containing a phenolate anion group.

Optionally, in some embodiments of the present disclosure, wherein one or more of the ligands of the platinum (II) complex include one of a substituted aryl group, a substituted heteroaromatic ring, or a substituted fused ring, wherein a substituent on the substituted heteroaromatic ring includes at least tert-butyl or deuterated tert-butyl.

Optionally, in some embodiments of the present disclosure, wherein the platinum (II) complex includes any one of the following compounds:

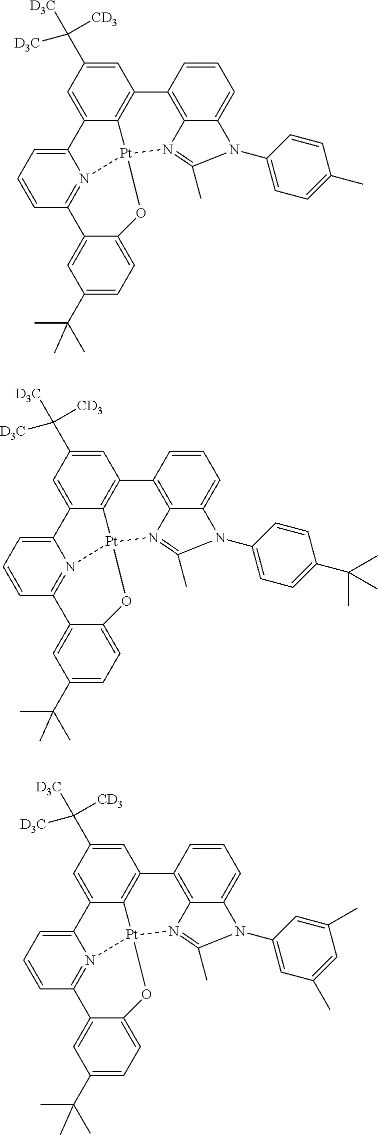

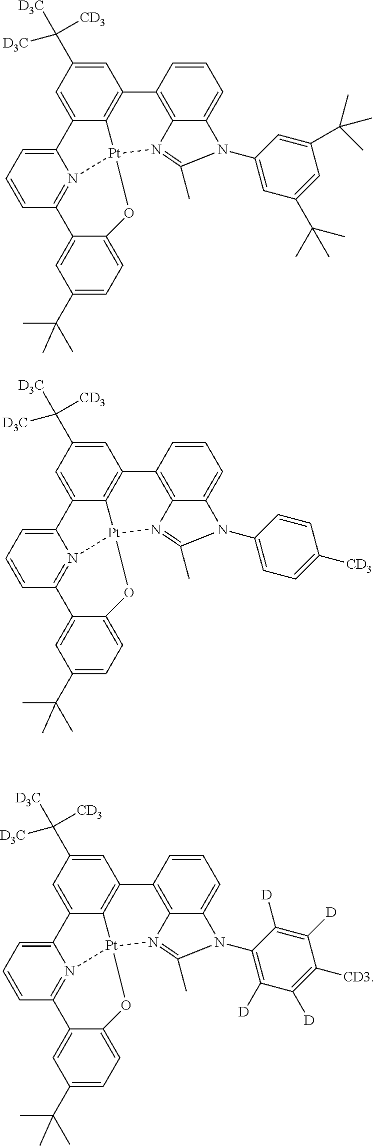

Optionally, in some embodiments of the present disclosure, wherein the first light-emitting layer further includes a hole injection layer between the first electrode and the first light-emitting sublayer, and a hole transport layer between the first light-emitting sublayer and the hole injection layer; and
the second light-emitting sublayer further includes an electron injection layer between the second electrode and the second light-emitting sublayer, and an electron transport layer between the second light-emitting sublayer and the electron injection layer.

Accordingly, the present disclosure further provides a display panel including a light-emitting device, wherein the light-emitting device includes:
a substrate; a first electrode disposed on the substrate;
a light-emitting functional layer disposed on a side of the first electrode away from the substrate, the light-emitting functional layer including a first light-emitting layer, a charge-generating layer, and a second light-emitting layer sequentially disposed on the first electrode, the first light-emitting layer including a first light-emitting sublayer, and the second light-emitting layer including a second light-emitting sublayer; and
a second electrode disposed on a side of the second light-emitting layer away from the charge-generating layer;
wherein a triplet lifetime of a material of the first light-emitting sublayer is longer than that of a material of the second light-emitting sublayer, and luminous efficiency of the material of the first light-emitting sublayer is less than that of the material of the second light-emitting sublayer.

Optionally, in some embodiments of the present disclosure, wherein the first light-emitting sublayer includes a first host material and a first doping material, the first doping material including a first phosphorescent light-emitting material; and
the material of the second light-emitting sublayer includes a second host material and a second doping material, the second doping material including a second phosphorescent light-emitting material.

Optionally, in some embodiments of the present disclosure, wherein the first doping material includes an iridium (III) complex, the second doping material includes a platinum (II) complex, and ligands of each of the iridium (III) complex and the platinum (II) complex are organic multidentate ligands.

Optionally, in some embodiments of the present disclosure, wherein one or more of the ligands of the iridium (III) complex include at least an organic compound containing a dibenzofuran substituent.

Optionally, in some embodiments of the present disclosure, wherein one or more of the ligands of the iridium (III) complex include at least a deuterium group.

Optionally, in some embodiments of the present disclosure, wherein the iridium (III) complex includes any one of the following compounds:

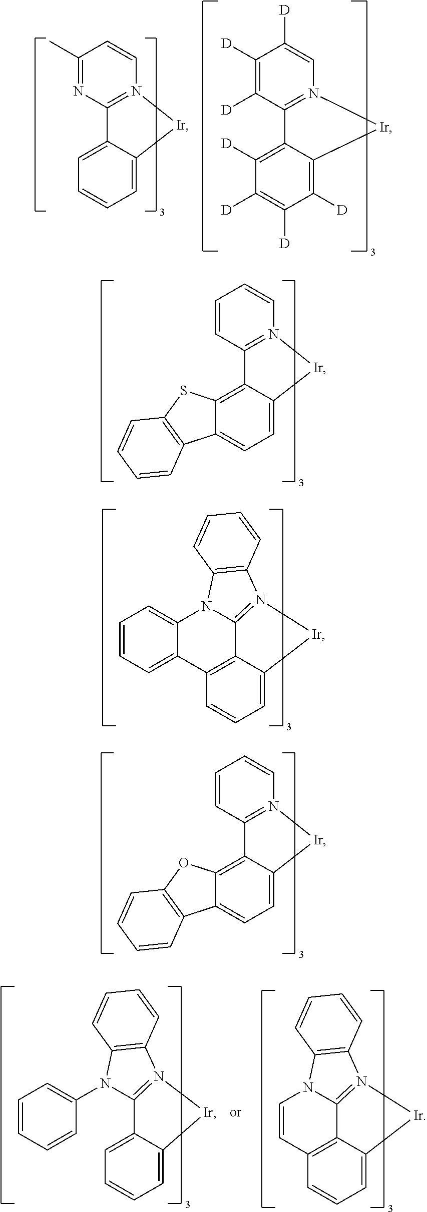

Optionally, in some embodiments of the present disclosure, wherein one or more of the ligands of the platinum (II) complex include an organic compound containing a phenolate anion group.

Optionally, in some embodiments of the present disclosure, wherein one or more of the ligands of the platinum (II) complex include one of a substituted aryl group, a substituted heteroaromatic ring, or a substituted fused ring, wherein a substituent on the substituted heteroaromatic ring includes at least tert-butyl or deuterated tert-butyl.

Optionally, in some embodiments of the present disclosure, wherein the platinum (II) complex includes any one of the following compounds:

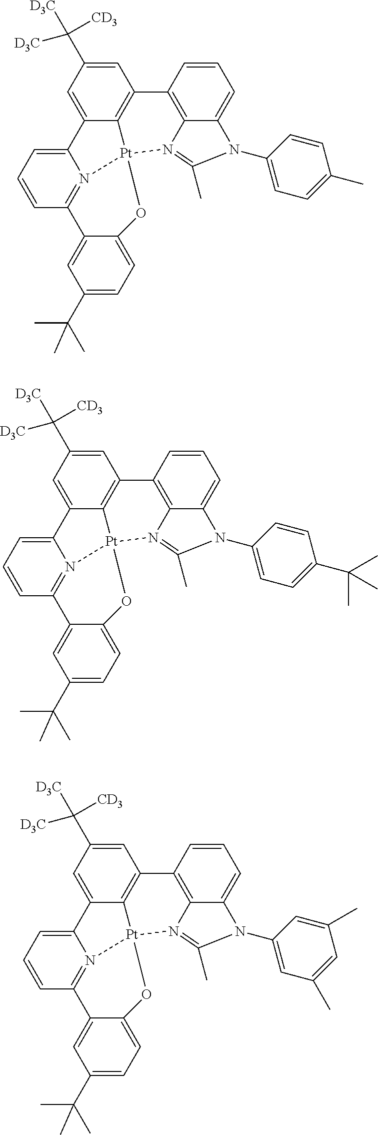

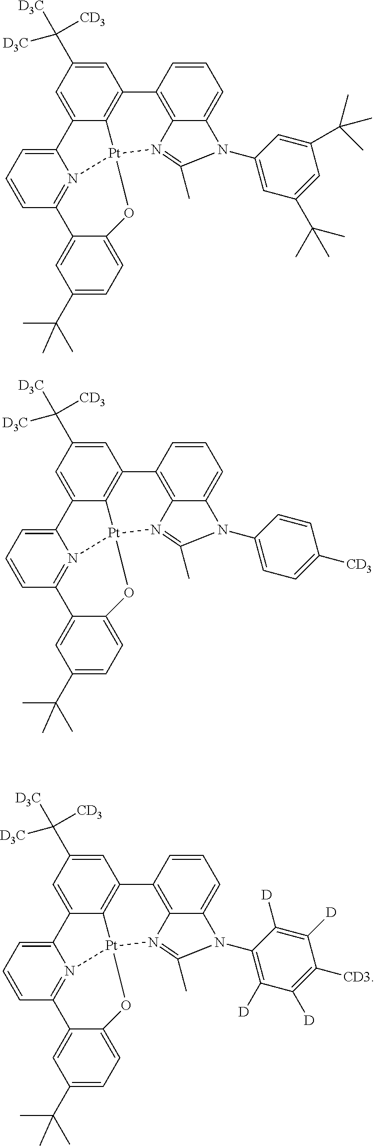

Optionally, in some embodiments of the present disclosure, wherein the first light-emitting layer further includes a hole injection layer between the first electrode and the first light-emitting sublayer, and a hole transport layer between the first light-emitting sublayer and the hole injection layer; and
the second light-emitting sublayer further includes an electron injection layer between the second electrode and the second light-emitting sublayer, and an electron transport layer between the second light-emitting sublayer and the electron injection layer.

### BRIEF DESCRIPTION OF THE DRAWINGS

In order to illustrate clearly the technical solutions in the embodiments of the present disclosure, the accompanying drawings which are to be used in the description of the embodiments are described briefly below. It will be apparent that the accompanying drawings in the following description are merely some of the embodiments of the present disclosure, and other drawings may be obtained on the basis of these drawings for those skilled in the art without involving any inventive effort.

FIG. 1 shows simulation results of contribution of respective light-emitting sublayer to luminous efficiency in a red light-emitting device.

FIG. 2 shows simulation results of contribution of respective light-emitting sublayer to luminous efficiency in a green light-emitting device.

FIG. 3 shows simulation results of contribution of respective light-emitting sublayer to luminous efficiency in a blue light-emitting device.

FIG. 4 shows measured results of contribution of respective light-emitting sublayer to luminous efficiency in a red light-emitting device.

FIG. 5 shows measured results of contribution of respective light-emitting sublayer to luminous efficiency in a green light-emitting device.

FIG. 6 shows measured results of contribution of respective light-emitting sublayer to luminous efficiency in a blue light-emitting device.

FIG. 7 is a schematic cross-sectional diagram of a light-emitting device 100 according to an embodiment of the present disclosure.

FIG. 8 is a graph of measured results of lifetime of an improved green light-emitting device according to the present disclosure.

FIG. 9 is a schematic diagram of a display panel 200 according to an embodiment of the present disclosure.

### DETAILED DESCRIPTION OF EMBODIMENTS

Embodiments of the present disclosure will be clearly and completely described below in conjunction with the accompanying drawings in the embodiments of the present disclosure. It will be apparent that the described embodiments are merely a part of the embodiments of the present disclosure, rather than all the embodiments. Based on the embodiments of the present disclosure, all other embodiments obtained by a person skilled in the art without involving any inventive effort are within the scope of the present disclosure. Furthermore, it is to be understood that the specific implementations described herein are for purposes of illustration and explanation only and are not intended to limit the application. In the present disclosure, orientation terms such as “upper” or “lower”, when used in the absence of any indication to the contrary, generally refer to the upper or lower of the device in its actual use or working state, specifically in a direction shown in the accompanying drawings, and the terms such as “inside” or “outside”, are related to a profile of the device.

An embodiment of the present disclosure provides a light-emitting device, including a substrate; a first electrode on the substrate; a light-emitting functional layer disposed on a side of the first electrode away from the substrate, the light-emitting functional layer including a first light-emitting layer, a charge-generating layer, and a second light-emitting layer which are sequentially disposed on the first electrode, the first light-emitting layer including a first light-emitting sublayer, and the second light-emitting layer including a second light-emitting sublayer; a second electrode disposed on a side of the second light-emitting layer away from the charge-generating layer. A triplet lifetime of a material of the first light-emitting sublayer is longer than that of a material of the second light-emitting sublayer, and a luminous efficiency of the material of the first light-emitting sublayer is less than that of the material of the second light-emitting sublayer.

An embodiment of the present disclosure further provides a display panel including the light-emitting device described above, which is described in detail below. It is to be noted that the order in which examples are described below is not intended to define the preferred order of the examples.

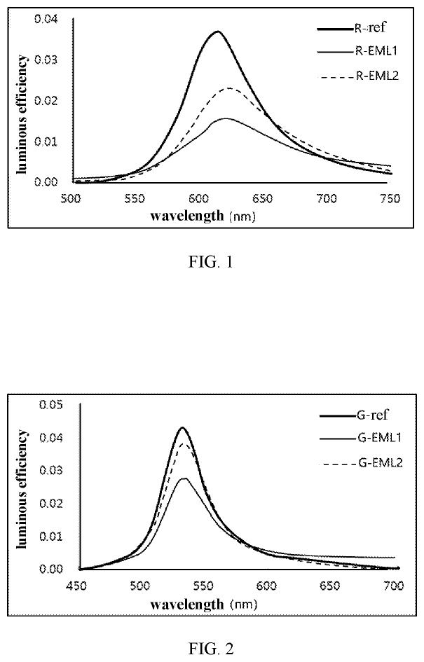

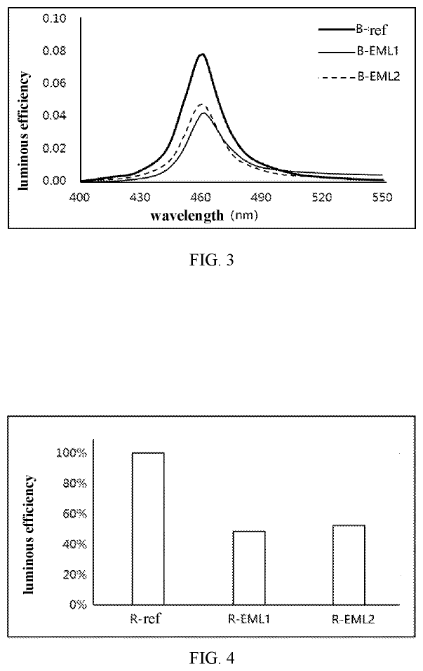

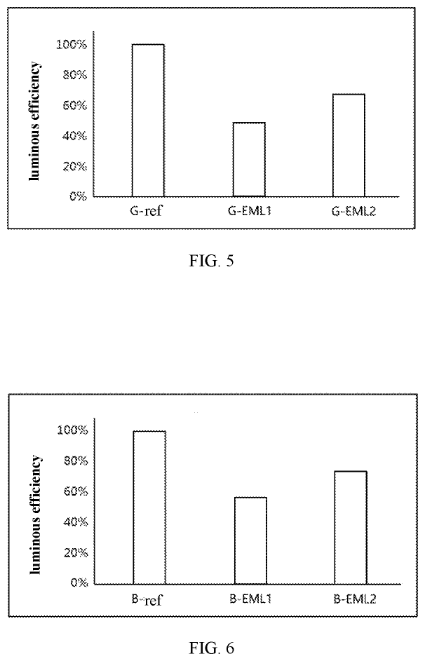

Theoretically, the brightness of a tandem light-emitting device may reach to two times that of a conventional light-emitting device having only a light-emitting layer, and similarly, the lifetime thereof may reach to two times that of the conventional light-emitting device under the same brightness. However, in practice, the brightness of the tandem light-emitting device is only about 1.6 times that of the conventional light-emitting device due to loss caused by microcavity effect and surface plasmon polaritons (SPPs) effect, so that the application of the tandem light-emitting device is limited. Referring to FIGS. 1 to 6, FIG. 1 shows simulation results of contribution of respective light-emitting sublayer to luminous efficiency in a red light-emitting device. FIG. 2 shows simulation results of contribution of respective light-emitting sublayer to luminous efficiency in a green light-emitting device. FIG. 3 shows simulation results of contribution of respective light-emitting sublayer to luminous efficiency in a blue light-emitting device. FIG. 4 shows measured results of contribution of respective light-emitting sublayer to luminous efficiency in a red light-emitting device. FIG. 5 shows measured results of contribution of respective light-emitting sublayer to luminous efficiency in a green light-emitting device. FIG. 6 shows measured results of contribution of respective light-emitting sublayer to a luminous efficiency in a blue light-emitting device. The reference symbol “R-ref” refers to a condition in which both light-emitting sublayers in the red light-emitting device emit light, the reference symbol “R-EML1” refers to a condition in which only the first light-emitting sublayer in the red light-emitting device emits light, and the reference symbol “R-EML2” refers to a condition in which only the second light-emitting sublayer in the red light-emitting device emits light. The reference symbol “G-ref” refers to a condition in which both light-emitting sublayers in the green light-emitting device emit light, the reference symbol “G-EML1” refers to a condition in which only the first light-emitting sublayer in the green light-emitting device emits light, and the reference symbol “G-EML2” refers to a condition in which only the second light-emitting sublayer in the green light-emitting device emits light. The reference symbol “B-ref” refers to a condition in which both light-emitting sublayers in the blue light-emitting device emit light, the reference symbol “B-EML 1” refers to a condition in which only the first light-emitting sublayer in the blue light-emitting device emits light, and the reference symbol “B-EML2” refers to a condition in which only the second light-emitting sublayer in the blue light-emitting device emits light.

From the simulation results of FIGS. 1 to 3, it can be found that the luminous efficiency of the tandem light-emitting device is less than the sum of the luminous efficiency of the first light-emitting sublayer and the luminous efficiency of the second light-emitting sublayer. The second light-emitting sublayer contributes more to the luminous efficiency of the tandem light-emitting device than the first light-emitting sublayer. This is particularly significant in the green light-emitting device.

From the measured results of FIGS. 4 to 6, it can be found that the luminous efficiency of the tandem light-emitting device is less than the sum of the luminous efficiency of the first light-emitting sublayer and the luminous efficiency of the second light-emitting sublayer. The second light-emitting sublayer contributes more to the luminous efficiency of the tandem light-emitting device than the first light-emitting sublayer. This is particularly significant in the green light-emitting device.

The simulation results shown in FIGS. 1 to 3 and the measured results shown in FIGS. 4 to 6 illustrate that the second light-emitting sublayer contributes more to the luminous efficiency of the light-emitting device 100 or the display panel 200 than the first light-emitting sublayer. In addition, it has been further found that the first light-emitting sublayer contributes more to the lifetime of the light-emitting device 100 or the display panel 200 than the second light-emitting sublayer.

### Example 1

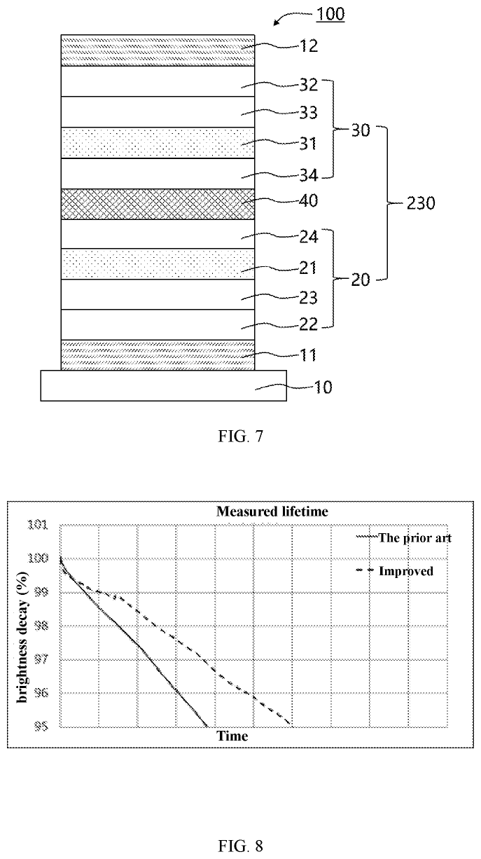

Referring to FIG. 7, it is a schematic cross-sectional diagram of a light-emitting device 100 according to an embodiment of the present disclosure.

An embodiment of the present disclosure provides a light-emitting device 100, including a substrate 10, a first electrode 11, a light-emitting functional layer 230, and a second electrode 12. The first electrode 11 is disposed on the substrate 10. The light-emitting functional layer 230 is disposed on a side of the first electrode 11 away from the substrate 10. The light-emitting functional layer 230 includes a first light-emitting layer 20, a charge-generating layer 40, and a second light-emitting layer 30 which are disposed on the first electrode 11 in sequence. The first light-emitting layer 20 includes a first light-emitting sublayer 21, The second light-emitting layer 30 includes a second light-emitting sublayer 31. The second electrode 12 is disposed on a side of the second light-emitting layer 30 away from the charge-generating layer 40. A triplet lifetime of a material of the first light-emitting sublayer 21 is longer than that of a material of the second light-emitting sublayer 31, and a luminous efficiency of the material of the first light-emitting sublayer 21 is less than that of the material of the second light-emitting sublayer 31.

Specifically, the light-emitting device 100 includes an anode and a cathode opposite to each other. The first electrode 11 may be the anode, and the second electrode 12 may be the cathode. The first light-emitting layer 20 and the second light-emitting layer 30 are arranged in series between the first electrode 11 and the second electrode 12. The second electrode 12 is disposed on a side of the first light-emitting layer 20 away from the first electrode 11.

Specifically, it has been found that the first light-emitting layer 20 contributes more to the lifetime of the light-emitting device 100 or the display panel 200 than the second light-emitting layer 30, and the triplet lifetime of the material of the first light-emitting sublayer 21 is longer than that of the material of the second light-emitting sublayer 31. The first light-emitting layer 20 with a long lifetime can greatly improve the lifetime of the light-emitting device 100 or the display panel 200.

Specifically, it has been found that the second light-emitting layer 30 contributes more to the luminous efficiency of the light-emitting device 100 or the display panel 200 than the first light-emitting layer 20, and the luminous efficiency of the material of the first light-emitting sublayer 21 is less than that of the material of the second light-emitting sublayer 31, or the luminous efficiency of the material of the second light-emitting sublayer 31 is greater than that of the material of the first light-emitting sublayer 21. The second light-emitting layer 30 with high luminous efficiency can greatly improve the luminous efficiency of the light-emitting device 100 or the display panel 200.

Specifically, the first light-emitting layer 20 having a longer lifetime is cooperated with the second light-emitting layer 30 having a higher luminous efficiency, so that the light-emitting device 100 or the display panel 200 has both a long lifetime and a high luminous efficiency, thereby greatly improving both the lifetime and the brightness of the light-emitting device 100 or the display panel 200.

In the embodiment, by selecting the first light-emitting sublayer 21 having the higher lifetime and the second light-emitting sublayer 31 having the higher luminous efficiency in the light-emitting device 100, it has been found that the first light-emitting sublayer 21 has a greater decisive influence on the lifetime than the second light-emitting sublayer 31, and the second light-emitting sublayer 31 has a greater decisive influence on the luminous efficiency than the first light-emitting sublayer 21. The first light-emitting sublayer 21 having the longer lifetime is cooperated with the second light-emitting sublayer 31 having the higher luminous efficiency, so that the light-emitting device 100 has both the long lifetime and high luminous efficiency, thereby greatly improving both the lifetime and the brightness of the light-emitting device 100.

In some embodiments, the first light-emitting sublayer 21 comprises a first host material and a first doping material, and the first doping material includes a first phosphorescent light-emitting material. The second light-emitting sublayer 31 comprises a second host material and a second doping material, and the second doping material includes a second phosphorescent light-emitting material.

Specifically, when a phosphorescent light-emitting material emits light, all excitons formed in a singlet excited state or a triplet excited state can participate in emission of light. Most of phosphorescent doping materials can realize rapid decay from the singlet state to the triplet state to emit light, whereby the luminous efficiency of the phosphorescent light-emitting material is greatly increased, compared with a fluorescent light-emitting material.

Specifically, further, the first doping material includes a first phosphorescent light-emitting material, and the second doping material includes a second phosphorescent light-emitting material. A lifetime of the first phosphorescent light-emitting material is longer than that of the second phosphorescent light-emitting material, and a luminous efficiency of the first phosphorescent light-emitting material is less than that of the second phosphorescent light-emitting material. The lifetime of the first phosphorescent light-emitting material is longer than that of the second phosphorescent light-emitting material, so that the lifetime of the first light-emitting layer 20 is longer than that of the second light-emitting layer 30. The luminous efficiency of the first phosphorescent light-emitting material is less than that of the second phosphorescent light-emitting material, so that the luminous efficiency of the first light-emitting layer 20 is less than that of the second light-emitting layer 30.

Further, a doping percentage by volume of the first doping material is in a range of 4%-12%, based on the total volume of the material of the first light-emitting layer 20.

Further, a doping percentage by volume of the second doping material is in a range of 4%-12%, based on the total volume of the material of the second light-emitting layer 30.

In some embodiments, the first doping material includes an iridium (III) complex, and the second doping material includes a platinum (II) complex. Ligands of each of the iridium (III) complex and the platinum (II) complex are organic multidentate ligands.

Specifically, the iridium (III) complex consists of a metal iridium (Ir) ion as a center and three bidentate ligands each of which possesses a unit negative charge. This six-coordinate metal iridium complex exhibits an octahedral configuration in the spatial domain. However, this kind of material has a corresponding disadvantage in that it is easy to form self-quenching after film formation (i.e., self-stacking), which results in low luminous efficiency of the light-emitting device. In contrast, the iridium (III) complex has a relatively high quantum efficiency and a short triplet lifetime, and has its own natural advantage in lifetime.

Specifically, the metal platinum ion in the platinum (Pt) (II) complex has a d⁸ electron configuration. Therefore, the platinum (II) complex tends to form a planar quadrilateral configuration by which one or more of the following different high-efficiency excitation states are present during a phosphorescent emission process: Ligand to Ligand Charge Transfer (LLCT), Metal to Ligand Charge Transfer (MLCT), Metal to Metal Charge Transfer (MMCT), and metal center charge transfer (dd*) excitation states in a monomer, thereby enhancing the luminous efficiency of the light-emitting device.

In some embodiments, one or more of the ligands of the iridium (III) complex include at least an organic compound containing a dibenzofuran substituent.

Specifically, a triplet excited state of dibenzofuran has a relatively slow radiation inactivation rate, and it is possible to allow part of the triplet state to transition to a singlet state by adjusting the degree of spin-orbit coupling and vibration coupling, thereby increasing the lifetime.

In some embodiments, one or more of the ligands of the iridium (III) complex comprise at least a deuterium group.

Specifically, a substituent of one or more of the ligands of the iridium complex includes deuterium. A carbon-deuterium bond is shorter, has higher bond energy and is more stable than a carbon-hydrogen bond, the lifetime of the light emitting device 100 can therefore be increased maximumly.

In some embodiments, the iridium (III) complex includes any one of the following compounds:

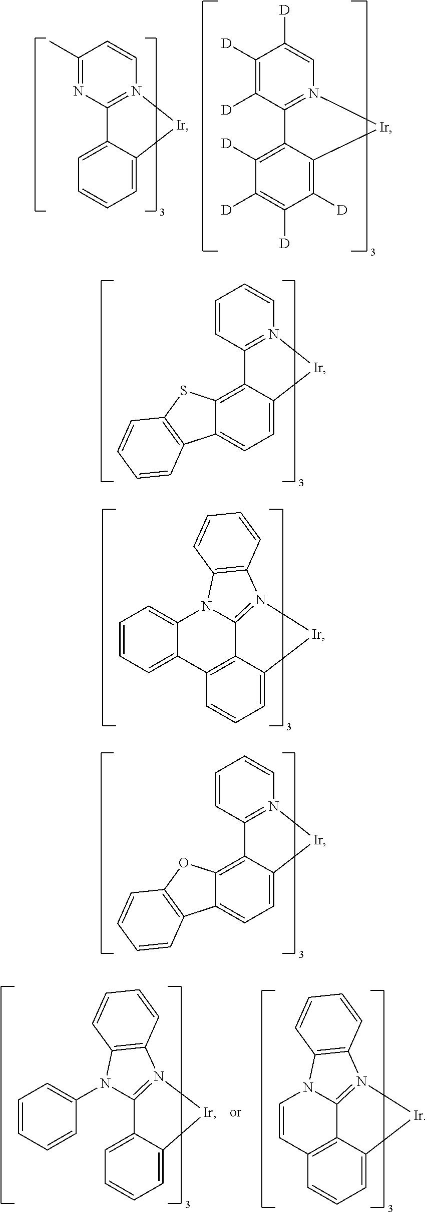

In some embodiments, one or more of the ligands of the platinum (II) complex include an organic compound containing a phenolate anion group.

Specifically, the phenolate anion group is a strong-field ligand, and can increase metal to ligand charge transfer (MLCT) of molecules after being introduced, thereby improving the luminous efficiency.

Specifically, the phenolate anion group may be represented as Ph-O⁻.

In some embodiments, one or more of the ligands of the platinum (II) complex comprise one of a substituted aryl group, a substituted heteroaromatic ring, or a substituted fused ring, wherein a substituent on the substituted heteroaromatic ring includes at least tert-butyl or deuterated tert-butyl.

Specifically, the tert-butyl group(s) at the terminal can reduce intermolecular π-π conjugation bonding, thereby avoiding triplet-triplet annihilation (TTA) effect and increasing the luminous efficiency of the platinum complex molecules of the light-emitting device.

Specifically, the tert-butyl group(s) needs to be introduced into the heteroaromatic or fused ring in order to prevent any two of the molecules from forming a fused ring, because the fused ring may have a relatively large π-π stacking and may quenche light. In addition, LUMO mainly falls on an electron withdrawing group, and the fused ring is a large electron withdrawing group.

In some embodiments, the platinum (II) complex includes any one of the following compounds:

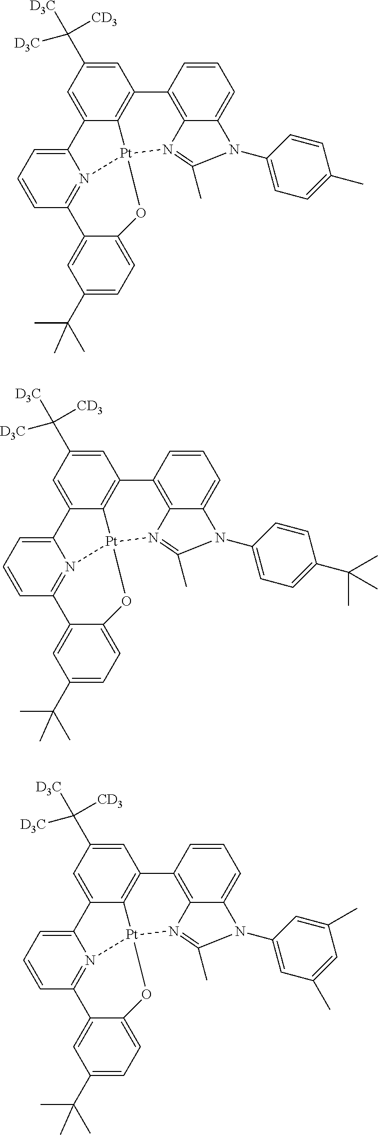

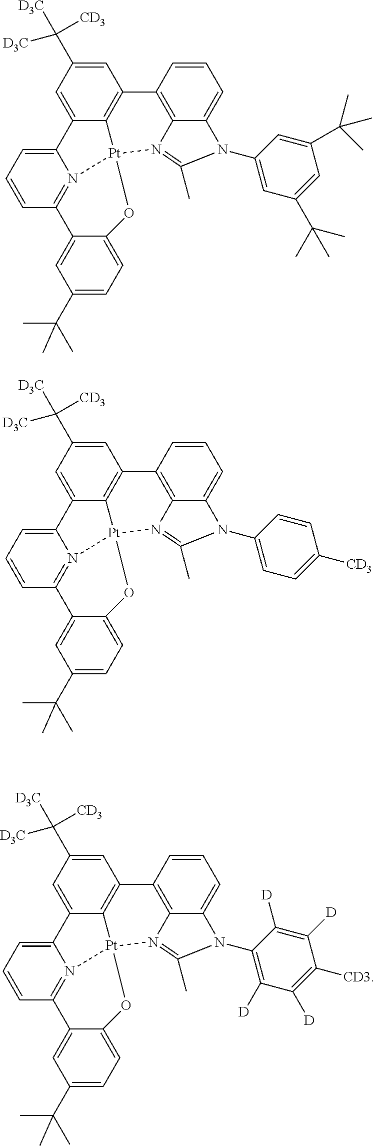

In some embodiments, the first light-emitting layer 20 further includes a hole injection layer 22 between the first electrode 11 and the first light-emitting sublayer 21, and a hole transport layer 23 between the first light-emitting sublayer 21 and the hole injection layer 22. The second light-emitting layer 30 further includes an electron injection layer 32 between the second electrode 12 and the second light-emitting sublayer 31, and an electron transport layer 33 between the second light-emitting sublayer 31 and the electron injection layer 32.

Specifically, the first light-emitting layer 20 may further include a first electron transport layer 24 between the charge-generating layer 40 and the first light-emitting sublayer 21, and the second light-emitting layer 30 may further include a first hole transport layer 34 between the charge-generating layer 40 and the second light-emitting sublayer 31.

Specifically, the first light-emitting layer 20 and the second light-emitting layer 30 may be any structure in the prior art, which are not limited herein.

Further, in some embodiments, the light-emitting device 100 further includes the charge-generating layer 40 disposed between the first light-emitting layer 20 and the second light-emitting layer 30.

Specifically, when carriers are injected from the first electrode 11 or/and the second electrode 12, the charge-generating layer 40 is capable of transferring holes or/and electrons between the first light-emitting layer 20 and the second light-emitting layer 30, so that the first light-emitting layer 20 and the second light-emitting layer 30 emit light independently, thereby improving current efficiency of the light-emitting device 100, and in turn improving the lifetime and luminous efficiency of the light-emitting device 100.

### Discussion of Experimental Data:

Light-emitting devices implemented in the prior art and in the present disclosure are tested for luminous efficiency and triplet lifetime herein. The results are shown in Table 1 and FIG. 8.

The structure of the light-emitting device in the prior art is same as that of the improved light-emitting device of the present disclosure, except that the materials of the first and second light-emitting layers 20 and 30 of the light-emitting device are same as each other in the prior art, while the improved green light-emitting device of the present disclosure employs the light-emitting device described in above embodiments, in which the first doping material is used in a doping percentage by volume of 4% to 12%, and the second doping material is used in a doping percentage by volume of 4% to 12%.

The measured data of luminous efficiency and lifetime between the light-emitting devices in the prior art and the improved green light-emitting device of the present disclosure are compared, as shown in Table 1. FIG. 8 is a graph of measured lifetime of the improved green light-emitting device of the present disclosure.

It can be seen from Table 1 that, compared with the light-emitting device of the prior art, where the first doping material includes an iridium complex and the second doping material includes a platinum complex in the improved green light-emitting device, the luminous efficiency of the improved light-emitting device is increased to 105%, and the lifetime is prolonged to 139%. The improvement for the lifetime is more significant.

TABLE 1
Measured data of luminous efficiency and lifetime

| | Luminous | |
|---|---|---|
| Test conditions | efficiency | Lifetime |
| Prior art | 100% | 100% |
| Improved green light-emitting device | 105% | 139% |

### Example 2

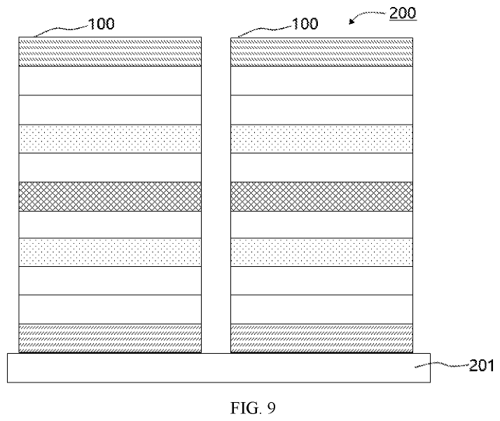

Referring to FIG. 9, it is a schematic diagram of a display panel 200 according to an embodiment of the present disclosure.

The present disclosure further provides a display panel 200, including the light-emitting device 100 of any one of embodiments described above.

Specifically, the display panel 200 includes a base 201 and a plurality of light-emitting devices 100 on the base 201.

Specifically, the plurality of light-emitting devices 100 may be white light-emitting devices. The display panel 200 may further include a color resist layer through which light emitted from the white light-emitting devices may be selectively transmitted to realize color display.

Specifically, the plurality of light-emitting devices 100 may include red light-emitting devices, green light-emitting devices, and blue light-emitting devices. At least one of the red light-emitting devices, the green light-emitting devices, or the blue light-emitting devices employs the light-emitting device 100 of any of the above embodiments.

The light-emitting device and the display panel according to an embodiment of the present disclosure are described above in detail. Specific examples are applied herein for illustration of the principles and implementation of the present disclosure. The description of the above embodiments is merely provided for purpose of understanding the method of the present disclosure and the core idea thereof. In addition, the specific implementation and scope of application may be varied in accordance with the teachings of the present disclosure for those skilled in the art. In summary, contents of the present specification should not be construed as limiting the application.

What is claimed is:

1. A light-emitting device, comprising:
a substrate; a first electrode disposed on the substrate;
a light-emitting functional layer disposed on a side of the first electrode away from the substrate, the light-emitting functional layer comprising a first light-emitting layer, a charge-generating layer, and a second light-emitting layer sequentially disposed on the first electrode, the first light-emitting layer comprising a first light-emitting sublayer, and the second light-emitting layer comprising a second light-emitting sublayer; and
a second electrode disposed on a side of the second light-emitting layer away from the charge-generating layer;
wherein a triplet lifetime of a material of the first light-emitting sublayer is longer than that of a material of the second light-emitting sublayer, and luminous efficiency of the material of the first light-emitting sublayer is less than that of the material of the second light-emitting sublayer.

2. The light-emitting device of claim 1, wherein the first light-emitting sublayer comprises a first host material and a first doping material, the first doping material comprising a first phosphorescent light-emitting material; and
the material of the second light-emitting sublayer comprises a second host material and a second doping material, the second doping material comprising a second phosphorescent light-emitting material.

3. The light-emitting device of claim 2, wherein the first doping material comprises an iridium (III) complex, the second doping material comprises a platinum (II) complex, and ligands of each of the iridium (III) complex and the platinum (II) complex are organic multidentate ligands.

4. The light-emitting device of claim 3, wherein one or more of the ligands of the iridium (III) complex comprise at least an organic compound containing a dibenzofuran substituent.

5. The light-emitting device of claim 3, wherein one or more of the ligands of the iridium (III) complex comprise at least a deuterium group.

6. The light-emitting device of claim 3, wherein the iridium (III) complex comprises any one of the following compounds:

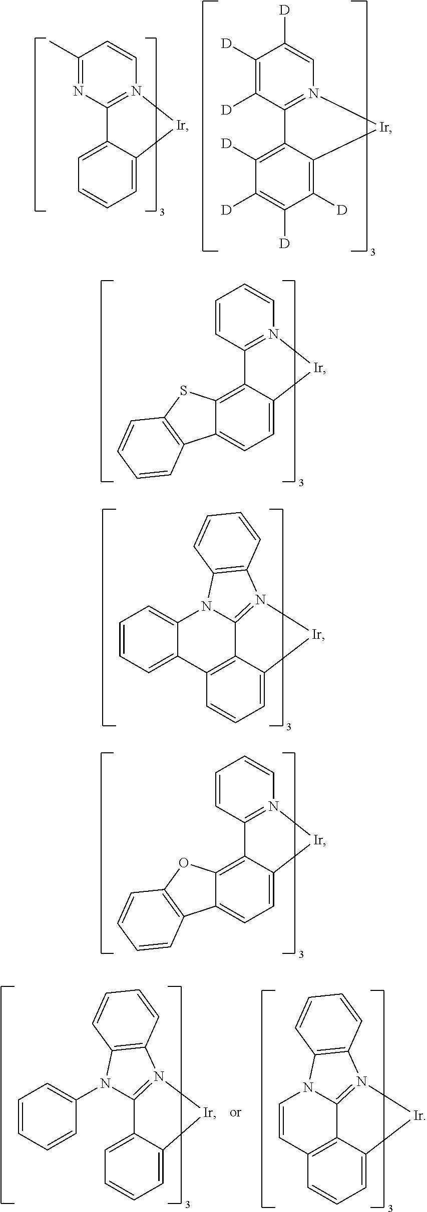

7. The light-emitting device of claim 3, wherein one or more of the ligands of the platinum (II) complex comprise an organic compound containing a phenolate anion group.

8. The light-emitting device of claim 3, wherein one or more of the ligands of the platinum (II) complex comprise one of a substituted aryl group, a substituted heteroaromatic ring, or a substituted fused ring, wherein a substituent on the substituted heteroaromatic ring comprises at least tert-butyl or deuterated tert-butyl.

9. The light-emitting device of claim 3, wherein the platinum (II) complex comprises any one of the following compounds:

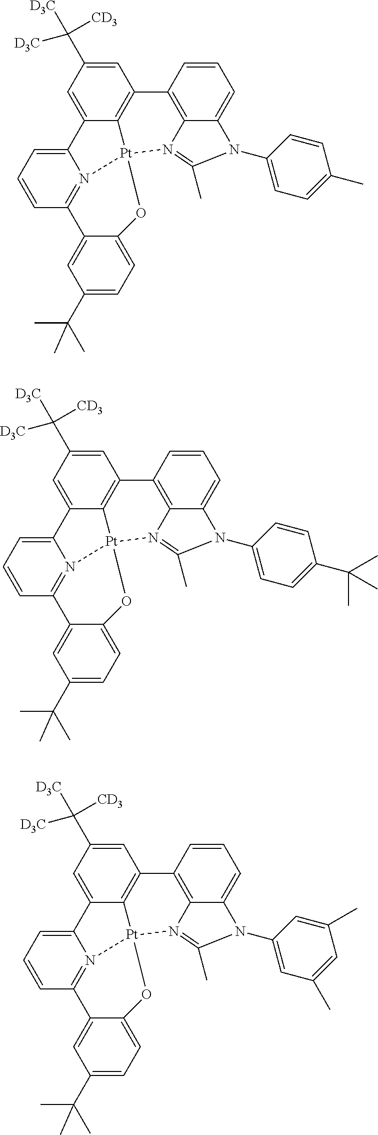

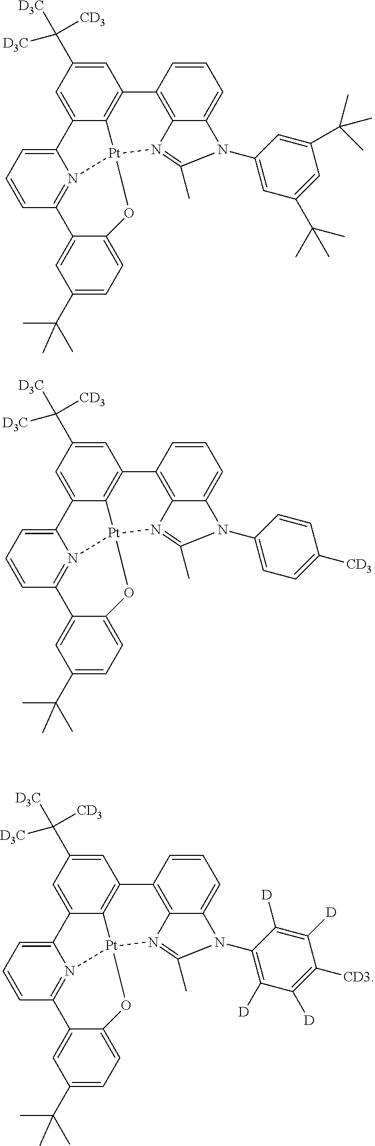

10. The light-emitting device of claim 3, wherein the first light-emitting layer further comprises a hole injection layer between the first electrode and the first light-emitting sublayer, and a hole transport layer between the first light-emitting sublayer and the hole injection layer; and
the second light-emitting sublayer further comprises an electron injection layer between the second electrode and the second light-emitting sublayer, and an electron transport layer between the second light-emitting sublayer and the electron injection layer.

11. A display panel comprising a light-emitting device, wherein the light-emitting device comprises:
a substrate; a first electrode disposed on the substrate;
a light-emitting functional layer disposed on a side of the first electrode away from the substrate, the light-emitting functional layer comprising a first light-emitting layer, a charge-generating layer, and a second light-emitting layer sequentially disposed on the first electrode, the first light-emitting layer comprising a first light-emitting sublayer, and the second light-emitting layer comprising a second light-emitting sublayer; and
a second electrode disposed on a side of the second light-emitting layer away from the charge-generating layer;
wherein a triplet lifetime of a material of the first light-emitting sublayer is longer than that of a material of the second light-emitting sublayer, and luminous efficiency of the material of the first light-emitting sublayer is less than that of the material of the second light-emitting sublayer.

12. The display panel of claim 11, wherein the first light-emitting sublayer comprises a first host material and a first doping material, the first doping material comprising a first phosphorescent light-emitting material; and
the material of the second light-emitting sublayer comprises a second host material and a second doping material, the second doping material comprising a second phosphorescent light-emitting material.

13. The display panel of claim 12, wherein the first doping material comprises an iridium (III) complex, the second doping material comprises a platinum (II) complex, and ligands of each of the iridium (III) complex and the platinum (II) complex are organic multidentate ligands.

14. The display panel of claim 13, wherein one or more of the ligands of the iridium (III) complex comprise at least an organic compound containing a dibenzofuran substituent.

15. The display panel of claim 13, wherein one or more of the ligands of the iridium (III) complex comprise at least a deuterium group.

16. The display panel of claim 13, wherein the iridium (III) complex comprises any one of the following compounds:

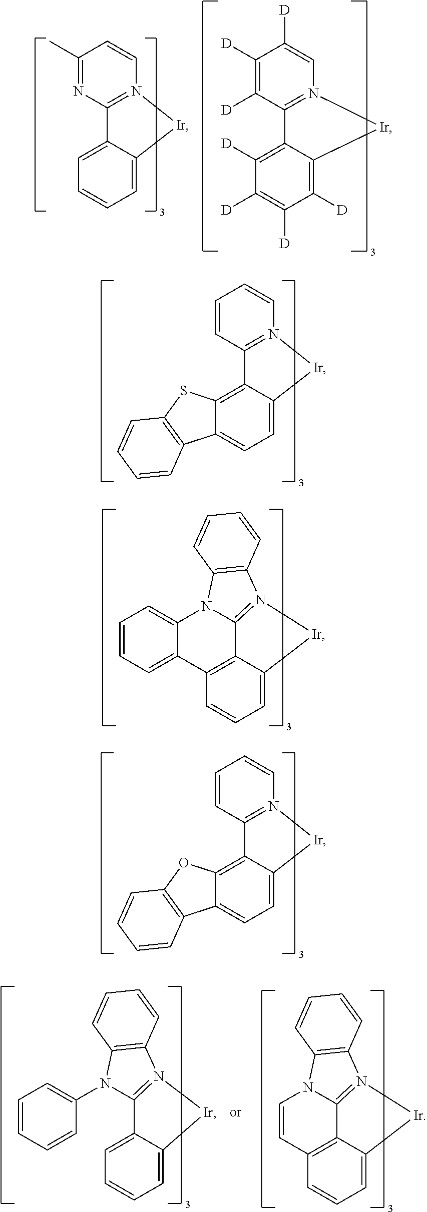

17. The display panel of claim 13, wherein one or more of the ligands of the platinum (II) complex comprise an organic compound containing a phenolate anion group.

18. The display panel of claim 13, wherein one or more of the ligands of the platinum (II) complex comprise one of a substituted aryl group, a substituted heteroaromatic ring, or a substituted fused ring, wherein a substituent on the substituted heteroaromatic ring comprises at least tert-butyl or deuterated tert-butyl.

19. The display panel of claim 13, wherein the platinum (II) complex comprises any one of the following compounds:

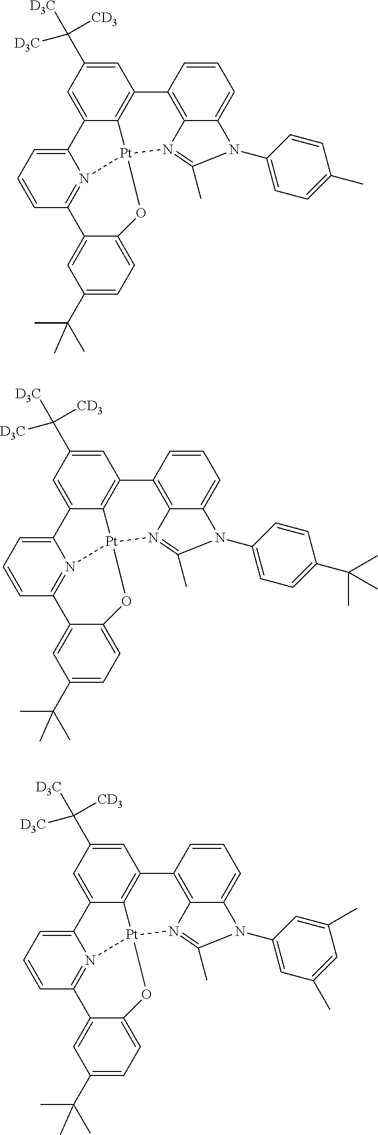

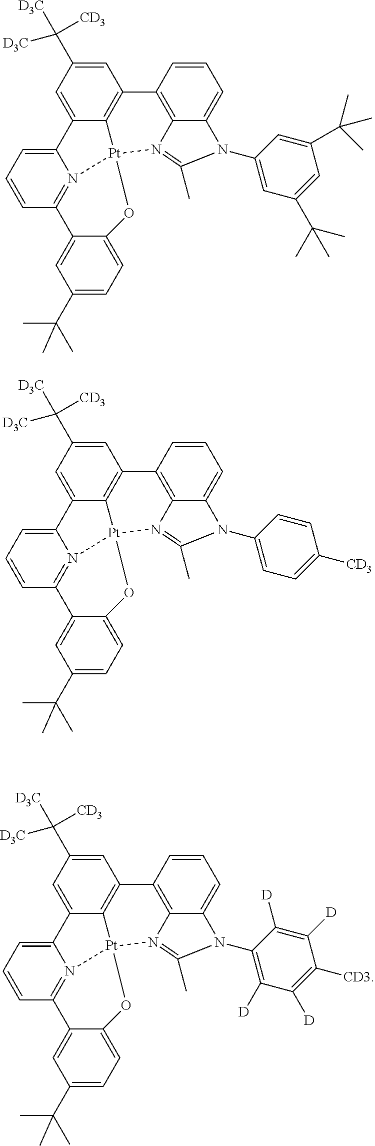

20. The display panel of claim 13, wherein the first light-emitting layer further comprises a hole injection layer between the first electrode and the first light-emitting sublayer, and a hole transport layer between the first light-emitting sublayer and the hole injection layer; and
the second light-emitting sublayer further comprises an electron injection layer between the second electrode and the second light-emitting sublayer, and an electron transport layer between the second light-emitting sublayer and the electron injection layer.
